(19) United States
(12) Patent Application Publication
(10) Pub. No.: US 2009/0201654 A1
(43) Pub. Date: Aug. 13, 2009

(54) METHOD AND SYSTEM FOR IMPROVING ELECTRICAL PERFORMANCE OF VIAS FOR HIGH DATA RATE TRANSMISSION

(76) Inventors: Lambert SIMONOVICH, Stittsville (CA); Herman Kwong, Kanata (CA)

Correspondence Address: CHRISTOPHER & WEISBERG, P.A., 200 EAST LAS OLAS BOULEVARD, SUITE 2040, FORT LAUDERDALE, FL, 33301, US

(21) Appl. No.: 12/367,635

(22) Filed: Feb. 9, 2009

Related U.S. Application Data
(60) Provisional application No. 61/027,071, filed on Feb. 8, 2008.

(51) Int. Cl. H05K 1/14; H05K 3/36

(52) U.S. Cl. 361/762; 29/852

(57) ABSTRACT

A method and system for reducing via hole parasitic effects on PCB transmission channels. In order to reduce the effects of excess via capacitance in PCB structures, PCB via modeling accuracy for high speed serial data transmissions is improved by utilizing lower permittivity reinforcement and z-axis conducting methods. A method to accomplish this includes creating a channel within the circuit board to accommodate a via hole, filling the created channel with a predetermined amount of dielectric material, forming the via hole, and electrically coupling the top layer of the structure to at least an inner signal substrate layer of the structure.

### CROSS-REFERENCE TO RELATED APPLICATION

The present invention is related to and claims priority to U.S. Provisional Patent Application No. 61/027,071, filed Feb. 8, 2008, entitled METHOD AND TECHNIQUE/APPARATUS TO MODEL VIA ELECTRICAL PERFORMANCE FOR HIGH DATA RATE TRANSMISSION, the entire contents of which is incorporated herein by reference.

### STATEMENT REGARDING FEDERALLY SPONSORED RESEARCH OR DEVELOPMENT

n/a

### FIELD OF THE INVENTION

The present invention relates generally to a method and system for improving the transmission of high bit rates or high frequencies within a layer to layer transition of a PCB substrate and more specifically to a method and system for improving the electrical performance of a via by controlling the dielectric properties with a known value of permittivity or dielectric constant Dk surrounding the via hole structure.

### BACKGROUND OF THE INVENTION

As the bit rate of data and communication systems continue to increase and Integrated Circuit (“IC”) driver rise times continue to decrease, channel simulations are becoming a necessity. Printed Circuit Boards (“PCBs”) used in these systems are typically created by stacking layers of fiberglass and copper until the system specifications are met. Etched copper traces from multiple layers are connected after the stacking process. A small hole, called a “via”, is drilled through the fiberglass stack and the barrel of the hole is metal plated. Each via appears as a small hole from the surfaces of the PCB. However, the through hole via parasitic effects on PCB transmission channels have become a factor affecting the Bit Error Rate (“BER”) performance. Simulation models and methods can be used to predict the via effects on system performance. These topology modeling and simulation techniques rely on defining the correct value of the relative permittivity (sometimes referred to as the dielectric constant, (“Dk”)) of the dielectric material surrounding the via in order to achieve better accuracy.

Attempts to model the parasitic effects of via holes have included simple lumped element models. However, as data rates are now driven to 6 Gbs/second and beyond, via model bandwidth and accuracy must increase to account for faster rise-times. Using an incorrect value of permittivity surrounding the via hole structure may lead to an over-optimistic channel performance prediction.

Another challenge faced today in high data rate transmission signal integrity is to reduce the via propagation discontinuity (delay) along transmission lines. This problem is compounded with multiple vias along the transmission lines stitching through a PCB in which critical signals could become contaminated by other signals.

PCB fabrication processes use a combination of fiberglass woven cloth and epoxy resin materials to laminate the layers in a non-homogeneous multi-layer stack-up. Electronic or E-Glass is one component used to fabricate fiberglass yarns. When glass fiber yarns are woven into sheets the “warp” yarns run the length of the fabric roll, while the “fill” or “weft” yarns run the width. The thread count is the number of warp yarns per inch by the number of fill yarns per inch.

Prepreg is the term used for a weave of glass fiber yarns impregnated with resin which is only partially cured. The combinations of yarn and resin thicknesses define the overall thickness of a prepreg sheet. Resin content is typically within the 40 to 70 percent range. It is a function of the thread count and the yarn diameters. Larger diameter glass yarn in a weave tend to be thicker and have a lower resin content, while smaller yarns are thinner and have a higher resin content.

When copper foil is attached to one or both sides of fully cured prepreg mats, the laminated sheet is called a core. Both core and prepreg sheets can be fabricated in various panel sizes and thicknesses. A multilayer PCB stackup can be fabricated with alternating layers of core and prepreg material. Depending on controlled impedance requirements for various transmission lines within the design, cores and prepregs are chosen to build up the required thicknesses to satisfy a particular trace etch geometry. The PCB manufacturing process dictates the preferred laminate thickness and resin content of the prepreg mats.

Inter-pair propagation delay mismatch (or “Laminate Weave Effect”) occurs due to differences in dielectric material properties (“Dk”). The additional losses introduced in differential transmission lines as a result of temporal asymmetries of the glass fiber yarns are due to the relative difference in propagation delay cased by the Weave Effect. As a signal propagates along a transmission line, its speed of propagation is directly proportional to the effective Dk of the dielectric material surrounding the trace. The characteristic impedence the signal sees at any point along the transmission line is inversely proportional to the effective Dk.

Due to the nature of the glass-resin construction of a typical PCB dielectric layer, the signal will experience a non-homogenous dielectric as it propagates parallel to the warp and weft of the glass yarns in the x/y direction. The effective Dk of any laminate is a function of the glass-to-resin ratio. As the signal propagates through the via, in the z-axis direction, it will experience a higher effective Dk, due to the anisotropic nature of the dielectric.

When using the appropriate value for Dk, the correct characteristic impedence of the trace geometry can be predicted using traditional software techniques known in the art. Laboratory measurements usually correlate well with the predicted results. However, using the same value of Dk when trying to model a particular via geometry typically results in poorer correlation to measurement. This is particularly true when trying to model and simulate the resonance stub effect caused by via transmissions to stripline layers in a multi-layer PCB.

Therefore, what is needed is a system and method for improving electrical performance of vias for high data rate transmission by using a known value of Dk to surround PCB via hole structures.

### SUMMARY OF THE INVENTION

The present invention advantageously provides a method and system for improving the transmission of high bit rates or high frequencies within a layer transition of a PCB substrate by minimizing dielectric permittivity surrounding a via hole structure.

According to one aspect of the invention, a method of improving signal integrity in a multi-layer circuit board is provided. The circuit board includes at least a top layer, an inner signal substrate layer, and a bottom layer. The method includes creating a channel within the circuit board to accommodate a via hole, filling the created channel with a predetermined amount of dielectric material with known dielectric constant, providing an inner signal substrate layer, forming the via hole, and electrically coupling the top layer to at least the inner signal substrate layer.

According to another aspect of the invention, a circuit board substrate is provided. The substrate includes a top layer and a bottom layer, an inner signal layer disposed between the top layer and the bottom layer, and a predetermined amount of dielectric material with known dielectric constant, where the dielectric material fills a channel formed between the top layer and the bottom layer, and the channel has dimensions to accommodate a via hole barrel. The via hole barrel extends through the dielectric material and electrically couples the top layer to the bottom layer.

According to yet another embodiment, a multi-layer circuit board substrate is provided where the substrate includes a top layer and a bottom layer, top circuitry and bottom circuitry, an inner signal layer disposed between the top layer and the bottom layer, and a predetermined amount of dielectric material with known dielectric constant. The dielectric material fills a channel formed between the top layer and the bottom layer and has dimensions to accommodate a via hole barrel. The substrate also includes a conducting device extending at least partially through the channel of dielectric material, where the conducting device electrically couples the top circuitry to the bottom circuitry.

### BRIEF DESCRIPTION OF THE DRAWINGS

A more complete understanding of the present invention, and the attendant advantages and features thereof, will be more readily understood by reference to the following detailed description when considered in conjunction with the accompanying drawings wherein:

FIG. 1 is an example of an exploded cross sectional view of a PCB pre-laminated stack-up for an epoxy filled plated through hole in accordance with the principles of the present invention;

FIG. 2 is a cross sectional via showing the post-laminated PCB structure prior to the drilling of via holes;

FIG. 3 is a cross sectional view showing the drilling process in the PCB substrate;

FIG. 4 is a cross sectional view showing the finished plated through via hole;

FIG. 5 is an alternate embodiment of the present invention illustrating an exploded cross sectional view of a PCB pre-laminated stack-up for a feed-through pin with a non-plated through hole;

FIG. 6 is a cross sectional view of the post-laminated PCB structure showing the feed-through pin via connecting the respective layers of a non-plated through hole;

FIG. 7 is a side view of the PCB structure having a partially shielded and plated via transmission line;

FIG. 8 is a side view of the PCB structure having a totally shielded transmission line structure;

FIG. 9 is a flowchart illustrating the steps to create the PCB structure of FIG. 7; and

FIG. 10 is a flowchart illustrating the steps to create the PCB structure of FIG. 8.

### DETAILED DESCRIPTION OF THE INVENTION

Before describing in detail exemplary embodiments that are in accordance with the present invention, it is noted that the embodiments reside primarily in combinations of apparatus components and processing steps related to implementing a system and method for improving the transmission of high bit rates or high frequencies within a layer to layer transition of a PCB substrate.

Accordingly, the system and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements.

The present invention improves PCB via performance for high speed serial data transmissions by reducing excess via capacitance. This is accomplished by utilizing lower permittivity reinforcement and z-axis conducting methods in order to better control the via parasitic capacitance.

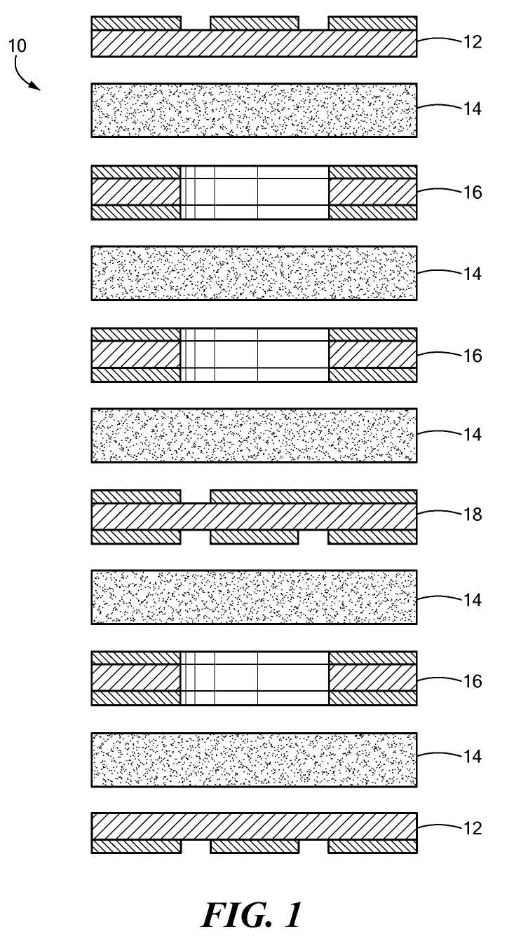

Referring now to the drawing figures in which like reference designators refer to like elements, FIG. 1 illustrates an exploded cross sectional view of a PCB pre-laminated substrate or stack-up 10 constructed in accordance with the principles of the present invention. This embodiment provides a printed conductor structure that utilizes a concentric dielectric material surrounding a plated via hole structure. In one embodiment, the dielectric material surrounding the plated through hole is of a low permittivity (Dk) resin or epoxy material, although the invention is equally adaptable to other types of dielectric material. Further, the number of layers shown in FIG. 1 and ensuing figures are exemplary and the PCB stack-up may incorporate a fewer or a greater number of layers.

In FIG. 1, a single sided prefabricated core laminate capper layer 12 is used on the top and on the bottom of the PCB stack-up 10. One or more low Dk resin sheets 14 are used in stack-up 10. Resin sheets 14 may or may not include reinforcement material. One or more pre-etched double sided core laminates 16 may be pre-drilled in accordance with the effective anti-pad clearance diameter. The drilled opening may be of any shape. The via barrel will eventually connect to a pre-etched inner signal layer 18.

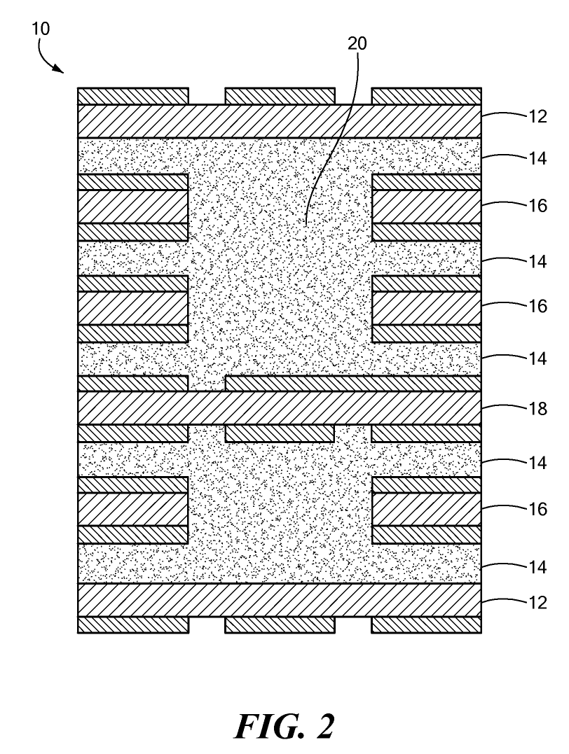

Referring to FIG. 2, a cross sectional view of a post-laminated PCB structure 10 prior to drilling is shown. The dielectric resin material 14 is applied or introduced with elevated temperature or pressure of combination of both into the respective holes by processes known in the art including heating and pressing the stack-up 10 of core laminates 16. This creates a resin-filled channel 20 through the circuit board large enough to accommodate a via barrel.

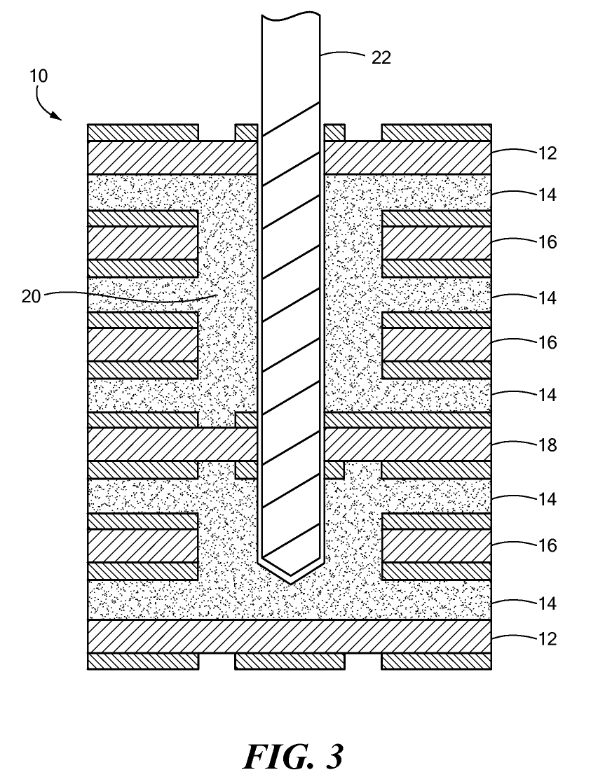

FIG. 3 is a cross sectional view of stack-up 10, showing a drilling process operation whereby a bit 22 is drilled through stack-up 10 and into the channel 20 created by the heating and pressing operation, as shown in FIG. 2.

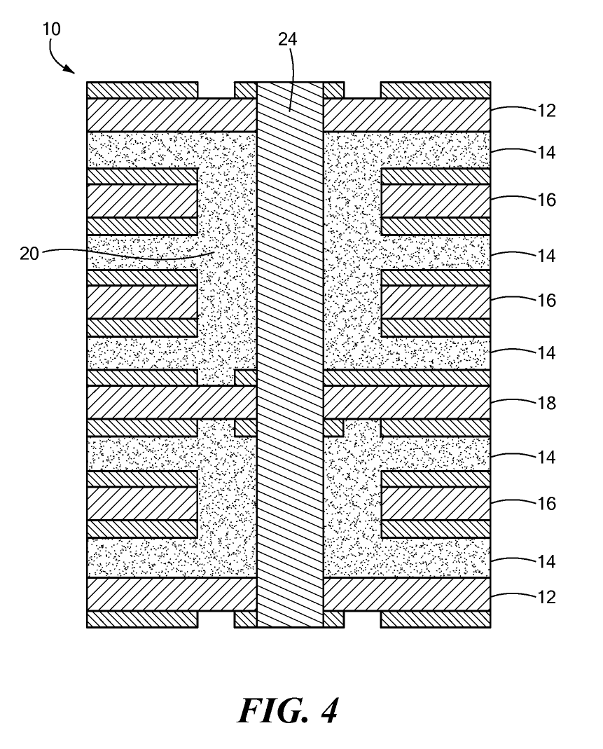

FIG. 4 illustrates the finished plated through hole via barrel 24 that, by a process known in the art as plating, electrically connects the top and bottom layers 12 of stack-up 10 to an inner signal layer 18. The embodiment shown in FIGS. 1-4 is applicable to any combination of substrate layers and any type of layer-to-layer interconnect.

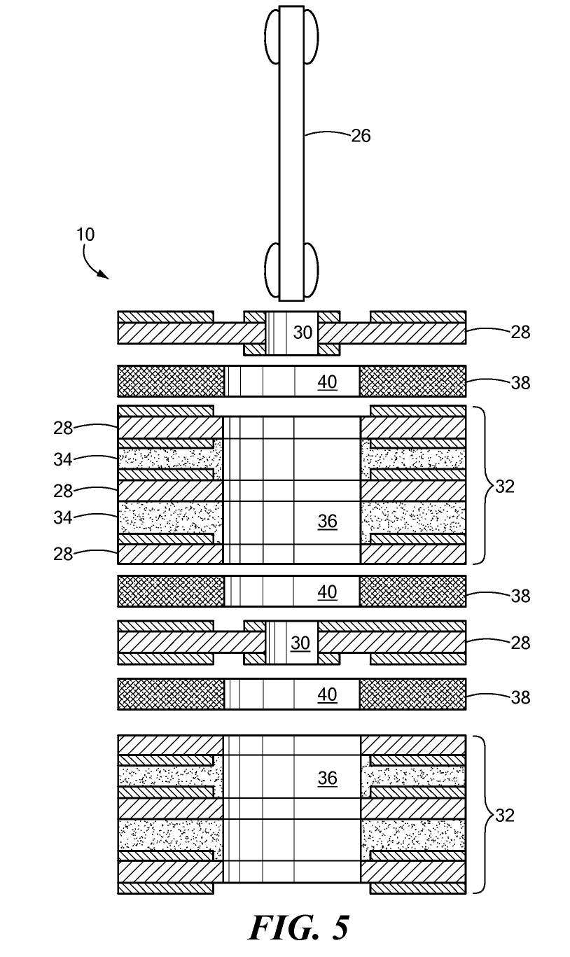

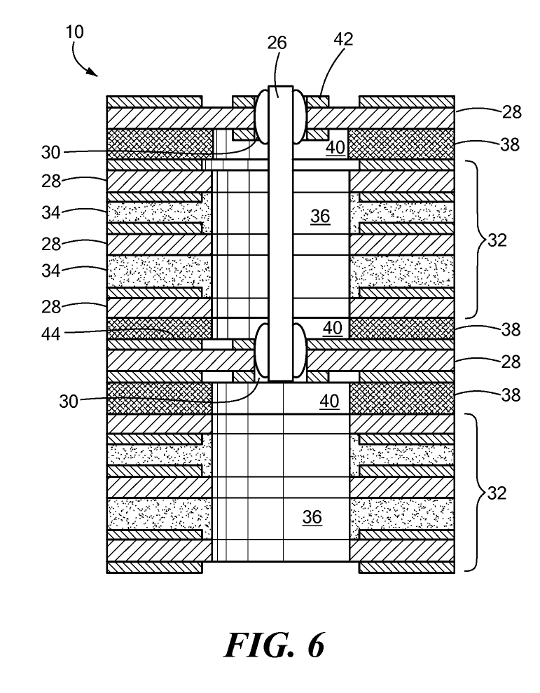

In an alternate embodiment shown in FIGS. 5-6, a stack-up 10 is shown having a feed-through pin 26 with a non-plated through hole 36. In this embodiment, the dielectric material surrounding a feed-through pin 26 is predominately air. The inter-layer connectivity of stack-up 10 is provided by a metallic pin 26. FIG. 5 shows the exploded cross sectional view of a PCB stack-up 10 having a plurality of pre-laminated layers 32. However, this embodiment is not limited to a particular number of substrate layers. Pin 26 is used to make the final interconnection between the layers. In one embodiment, pin 26 is a compliant, press-fitted pin, however, the invention is not restricted to a particular type of feed-through device or layer-interconnection method or device.

Stack-up 10 includes one or more single or double-sided PCB laminated cores 28, having pre-plated holes 30. Within stack-up 10, there are one or more pre-laminated multilayer PCB structures 32. The structures 32 can be arranged to have alternating core 28 and prepreg 34 laminates. The laminates may have unplated holes 36 predrilled therein and may be but need not be drilled in accordance with the effective anti-pad clearance diameter. The opening created by unplated holes 36 may be of any shape or dimension. Stack-up 10 may include bonding material 38 that includes a clearance hole 40 that also may be but need not be limited to the effective anti-pad clearance diameter. Hole 40 of bonding material 38 may be of any shape of dimension.

FIG. 6 is a cross sectional view of the finished PCB laminated stack-up 10 of this embodiment. Here, pin 26 is press fitted into structure 10 thereby connecting top layer 42 to inner layer 44.

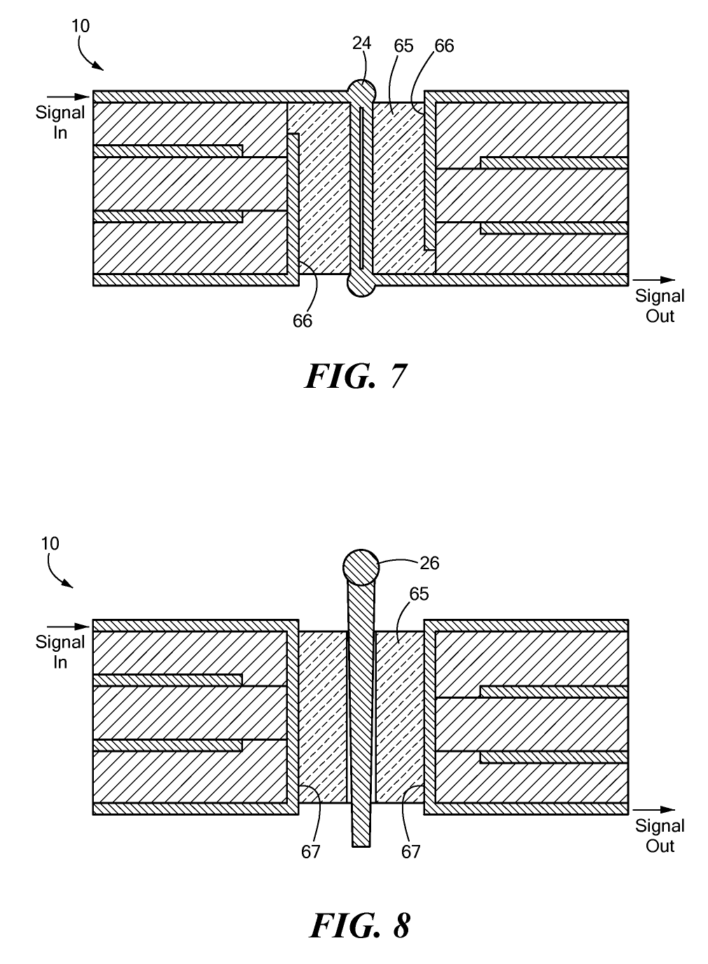

FIG. 7 displays a cross-sectional view of the stack-up 10 having a partially shielded via transmission line structure. In this embodiment, in order to preserve the incoming signal integrity and continuity, a hole large enough to accommodate a reliable plated through hole via 24 is drilled into stack-up 10 and the hole filled in with dielectric material 65. The result of the process creates a partially shielded via transmission line structure 66, which limits the dielectric permittivity surrounding the via hole structure to a known value.

FIG. 8 of this embodiment displays a cross sectional view of a totally shielded transmission line structure. Here, the feed-through pin 26 provides the electrical connection between the top circuitry and bottom circuitry of the structure. This structure results in a complete shield 67 surrounding the via pin 26.

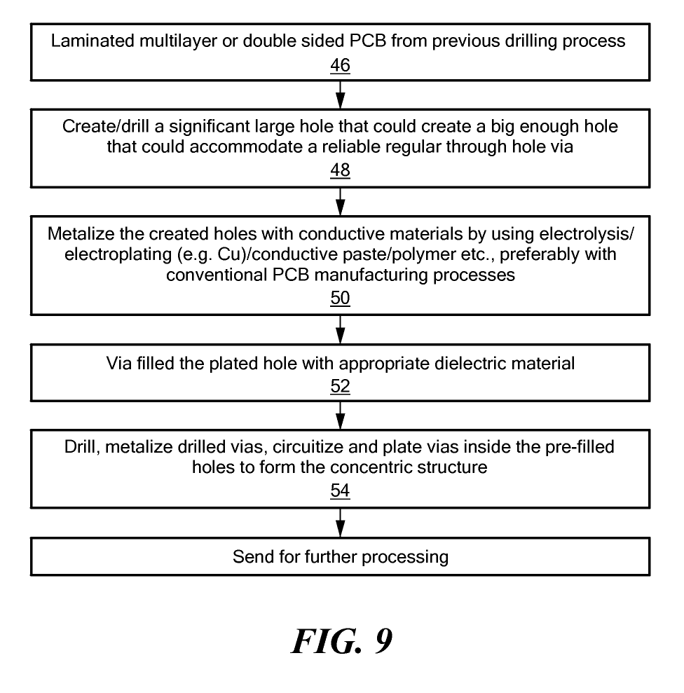

FIG. 9 is a flowchart of a manufacturing process used to create the structure shown in FIG. 7. This process creates a substrate that improves the transmission of high frequency signals within a multi-layer substrate while minimizing dielectric permittivity surrounding a via hole structure. Initially, a multilayer or double-sided PCB from a previous drilling process is laminated, at step 46. A hole is then created in the structure where the hole is large enough to accommodate a reliable regular through-hole via, at step 48. The created holes are then metalized with conductive materials by conventional processes known in the art (i.e., electrolysis/electroplating (e.g. Cu), conductive paste/polymer etc.), at step 50. The plated holes are then filled with dielectric material 65, at step 52. The via holes 24 are then drilled, metalized, connected to the circuitry within the structure and plated inside the pre-filled substrate holes to form a concentric structure, at step 54.

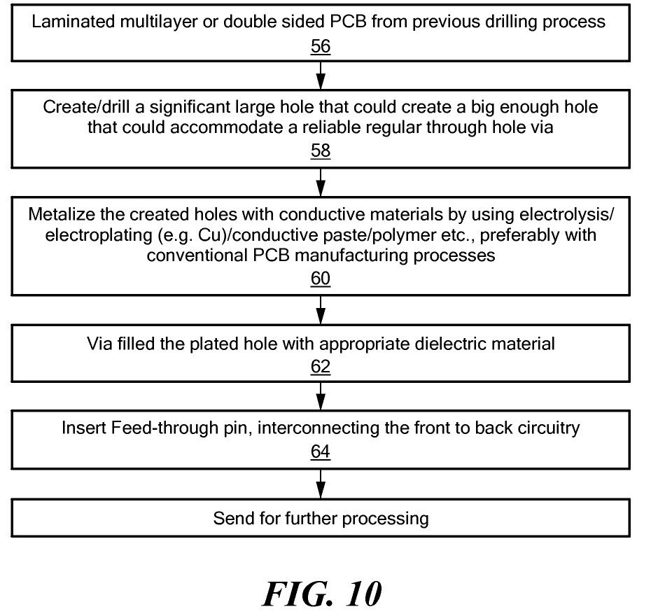

FIG. 10 is a flowchart of an alternate manufacturing process used to create the structure shown in FIG. 8. A multilayer or double-sided PCB from a previous drilling process is laminated, at step 56. A hole is then created in the structure where the hole is large enough to accommodate a reliable regular through-hole via, at step 58. The created holes are then metalized with conductive materials by conventional processes known in the art (i.e., electrolysis/electroplating (e.g. Cu), conductive paste/polymer etc.), at step 60 to form a total via shield 67. The plated holes are then filled with dielectric material 65, at step 62. The preceding steps are similar to those steps used to form the substrate in FIG. 7. However, in this alternate process, instead of drilling and plating the via holes 24, a feed-through pin 26 is inserted within the multi-layered substrate, in order to connect the front and back circuitry of the substrate, at step 64.

In addition, unless mention was made above to the contrary, it should be noted that all of the accompanying drawings are not to scale. Significantly, this invention can be embodied in other specific forms without departing from the spirit or essential attributes thereof, and accordingly, reference should be had to the following claims, rather than to the foregoing specification, as indicating the scope of the invention.

What is claimed is:

1. A method of improving signal integrity in a multi-layer circuit board, the circuit board having at least a top layer, an inner signal substrate layer, and a bottom layer, the method comprising:
creating a channel within the circuit board to accommodate a via hole;
filling the created channel with a predetermined amount of dielectric material with known dielectric constant;
providing an inner signal substrate layer;
forming the via hole; and
electrically coupling the top layer to at least the inner signal substrate layer.

2. The method of claim 1, wherein electrically coupling the top layer to at least the inner signal substrate layer includes inserting a plated via hole barrel within the channel, the via hole barrel containing the via hole, the barrel extending from the top layer to at least the inner signal substrate layer.

3. The method of claim 1, wherein the circuit board further includes one or more core laminates wherein each core laminate includes a pre-formed space.

4. The method of claim 3, wherein creating a channel to accommodate a via hole includes introducing the dielectric material into the pre-formed space in each of the one or more core laminates.

5. The method of claim 4, wherein introducing the dielectric material into the pre-formed space in each of the one or more core laminates is accomplished by heating the circuit board.

6. The method of claim 4, wherein introducing the dielectric material into the pre-formed space in each of the one or more core laminates is accomplished by pressing the circuit board.

7. The method of claim 2, further comprising at least partially plating the created channel.

8. The method of claim 1, wherein the dielectric material forms at least a partially shielded channel formed between the top layer and the bottom layer.

9. The method of claim 1, further comprising laminating the circuit board with homogenous bonding materials with a desired dielectric constant.

10. A circuit board substrate comprising:
a top layer and a bottom layer;
an inner signal layer disposed between the top layer and the bottom layer; and
a predetermined amount of dielectric material with known dielectric constant, the dielectric material filling a channel formed between the top layer and the bottom layer, the channel having dimensions to accommodate a via hole barrel;
wherein the via hole barrel extends through the dielectric material, the via hole barrel electrically coupling the top layer to the bottom layer.

11. The circuit board substrate of claim 10, further including one or more core laminates, each core laminate including a pre-formed space therein.

12. The circuit board substrate of claim 11, wherein the dielectric material is introduced into the pre-formed space in each of the one or more core laminates.

13. The circuit board substrate of claim 12, wherein the dielectric material is introduced into the pre-formed space in each of the one or more core laminates by heating the circuit board substrate.

14. A multi-layer circuit board substrate comprising:
a top layer and a bottom layer;
top circuitry and bottom circuitry;
an inner signal layer disposed between the top layer and the bottom layer;
a predetermined amount of dielectric material with known dielectric constant, the dielectric material filling a channel formed between the top layer and the bottom layer, the channel having dimensions to accommodate a via hole barrel; and
a conducting device extending at least partially through the channel of dielectric material, the conducting device electrically coupling the top circuitry to the bottom circuitry.

15. The circuit board substrate of claim 14, wherein the conducting device is a metallic feed-through pin.

16. The circuit board substrate of claim 14, further including one or more core laminates, each core laminate including a pre-plated hole therein wherein the dielectric material is air.

17. The circuit board substrate of claim 14, wherein the substrate is comprised of alternating layers of core and prepreg material.

18. The circuit board substrate of claim 14, wherein the dielectric material forms a fully shielded channel formed between the top layer and the bottom layer.

19. The circuit board substrate of claim 14, further comprising one or more layers of bonding material, each layer of bonding material including a clearance hole through which the conducting device extends.

20. The circuit board substrate of claim 14, wherein the dielectric material is air.
